(19) United States
(12) Patent Application Publication
(10) Pub. No.: US 2019/0063463 A1
(43) Pub. Date: Feb. 28, 2019

(54) ELECTRONIC DEVICE AND HEAT DISSIPATION FAN

(71) Applicant: Lenovo (Beijing) Co., Ltd., Beijing (CN)

(72) Inventor: Zizhou JIA, Beijing (CN)

(21) Appl. No.: 15/941,184

(22) Filed: Mar. 30, 2018

(30) Foreign Application Priority Data
Aug. 23, 2017 (CN) 201710730563.X

(51) Int. Cl. F04D 29/66; F04D 29/28; F04D 29/42; H05K 7/20

(52) U.S. Cl. CPC F04D 29/666; H05K 7/20172; F04D 29/4206; F04D 29/282

(57) ABSTRACT

A heat dissipation fan includes a shaft and a plurality of blades configured along a circumferential direction of the shaft. The plurality of blades includes one or more long blades and one or more short blades shorter than the one or more long blades. A head portion of each of the one or more long blades is coupled to the shaft. Each of the one or more short blades is disposed close to a tail portion of one of the one or more long blades.

### CROSS-REFERENCES TO RELATED APPLICATION

This application claims priority to Chinese Patent Application No. 201710730563.X, filed on Aug. 23, 2017, the entire contents of which are hereby incorporated by reference.

### TECHNICAL FIELD

The present disclosure generally relates to the technical field of electronic devices and, more particularly, to a heat dissipation fan for cooling heat-generating components of an electronic device, and an electronic device having such heat dissipation fan.

### BACKGROUND

Many electronic devices are installed with a heat dissipation fan for cooling heat-generating components thereof, thus realizing heat dissipation. For some electronic devices, such as a notebook, as the overall volume is designed to be smaller and smaller, the space for installing the heat dissipation fan keeps decreasing, which cause high requirements on the soundless performance of the heat dissipation fan. However, the existing heat dissipation fans that include blades having the same or similar shape and dimension often generate a relatively high level of noise, so as to dissatisfy the growing requirements on the soundless performance of the heat dissipation fan. Thus, how to further reduce the noise generated by the heat dissipation fan has been a problem to be solved by those skilled in the relevant art.

### BRIEF SUMMARY OF THE DISCLOSURE

In accordance with the disclosure, there is provided a heat dissipation fan including a shaft and a plurality of blades configured along a circumferential direction of the shaft. The plurality of blades includes one or more long blades and one or more short blades shorter than the one or more long blades. A head portion of each of the one or more long blades is coupled to the shaft. Each of the one or more short blades is disposed close to a tail portion of one of the one or more long blades.

Also in accordance with the disclosure, there is provided an electronic device including a heat-generating component and a heat dissipation fan. The heat dissipation fan includes a shaft and a plurality of blades configured along a circumferential direction of the shaft. The plurality of blades includes one or more long blades and one or more short blades shorter than the one or more long blades. A head portion of each of the one or more long blades is coupled to the shaft. Each of the one or more short blades is disposed close to a tail portion of one of the one or more long blades.

### BRIEF DESCRIPTION OF THE DRAWINGS

In order to more clearly illustrate technical solutions in embodiments of the present disclosure, drawings for describing the embodiments are briefly introduced below. Obviously, the drawings described hereinafter are only some embodiments of the present disclosure, and it is possible for those ordinarily skilled in the art to derive other drawings from such drawings without creative effort.

FIG. 1 illustrates a front view of an example of a heat dissipation fan;

FIG. 2 illustrates a side view of an example of a heat dissipation fan;

FIG. 3 illustrates a back view of an example of a heat dissipation fan; and

FIG. 4˜FIG. 6 illustrate schematic views of examples showing arrangement of long blades and short blades in different manners.

In the accompanying drawings: 1—shaft; 2—long blade; 3—short blade; 4—connection ring.

### DETAILED DESCRIPTION

Various solutions and features of the present disclosure will be described hereinafter with reference to the accompanying drawings. Obviously, the disclosed embodiments are merely some but not all of embodiments of the present disclosure. Based on the disclosed embodiments, other embodiments obtainable by those ordinarily skilled in the art without creative labor shall all fall within the scope of the present disclosure. Further, in the specification, descriptions of well-known structures and technologies are omitted to avoid obscuring concepts of the present disclosure.

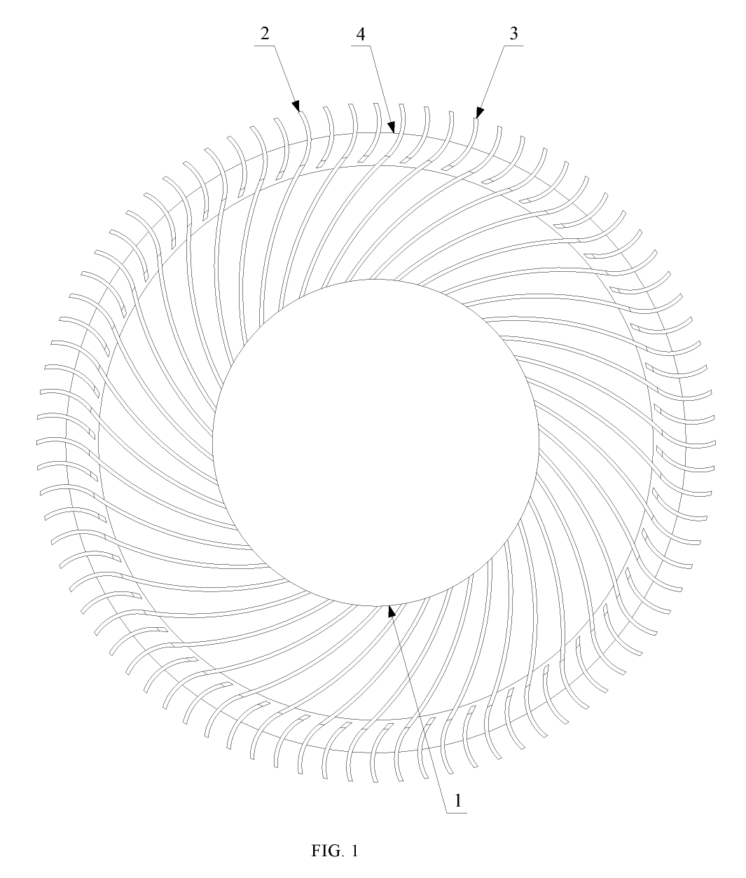

The present disclosure provides an improved heat dissipation fan. Compared with the existing technologies, the disclosed heat dissipation fan generates less noise during operation, and can meet the relatively high requirements on the soundless performance. FIG. 1 illustrates a front view of an example of a heat dissipation fan. As shown in FIG. 1, the heat dissipation fan includes a shaft 1 and a plurality of blades disposed at a periphery of the shaft 1. The plurality of blades may include a plurality of long blades 2 and a plurality of short blades 3, where the length of a short blade 3 is smaller than the length of a long blades 2. In some embodiments, the heat dissipation fan further includes a connection ring 4.

In some embodiments, the plurality of long blades 2 and short blades 3 are arranged alternately. For example, a short blade 3 may be disposed between two long blades 2. Further, head portions of the long blades 2 may be coupled to the shaft 1, and the short blades 3 may be disposed close to tail portions of the long blades 2. The tail portion of a long blade 2 refers to an end of the long blade 2 that is distal to the shaft 1.

When the shaft 1 drives the long blades 2 and the short blade 3 to rotate, airstream may flow between the blades. For example, in regions close to the shaft 1, airstream flows between two adjacent long blades 2. In the disclosed heat dissipation fan, one or more short blades 3 may be disposed between two adjacent long blades 2. Therefore, when the airstream flows towards the tail portions of the long blades 2, i.e., regions where the short blades are arranged, the short blades 3 may disperse the airstream, realizing dispersion of tail pulse of the fluid field of the heat dissipation fan. As such, the peak value of the acoustic field of the noise is reduced, resulting in the reduction of acoustic pressure. Accordingly, the disclosed heat dissipation fan can satisfy the growing requirements of soundless performance.

In some other embodiments, the plurality of blades may include a plurality of long blades 2 and a plurality of short blades 3. The plurality of short blades 3 may be disposed at a periphery of the shaft 1. For example, the plurality of short blades 3 and the plurality of long blades 2 may be disposed alternately. The configuration of multiple short blades 3 may better disperse the airstream, such that the acoustic pressure of the heat dissipation fan can be further reduced and the soundless performance of the heat dissipation fan can be improved.

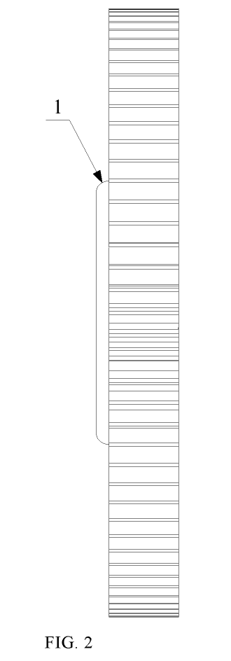

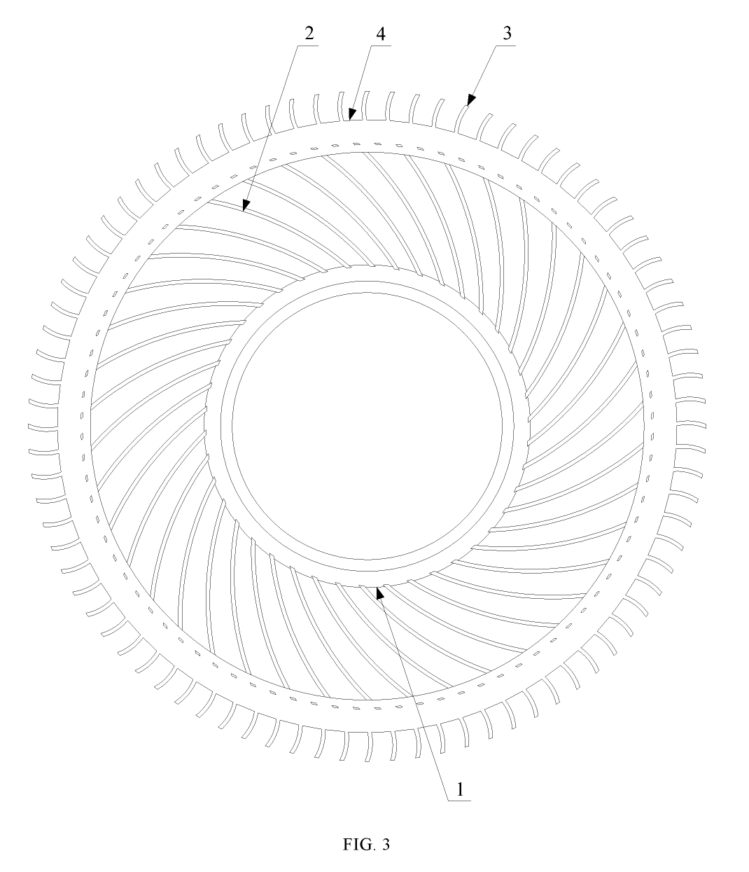

Further, the plurality of long blades 2 and the plurality of short blades 3 may be arranged alternately in various manners. FIG. 2 illustrates a side view of an example of a heat dissipation fan, and FIG. 3 illustrates a back view of an example of a heat dissipation fan. As shown in FIG. 2 and FIG. 3, and with reference to FIG. 1, the plurality of short blades 3 and the plurality of long blades 2 may be disposed alternately in a uniform manner. That is, one short blade 3 may be disposed between each two adjacent long blades 2 along a circumferential direction of the shaft 1. In this example, the airstream may be dispersed more evenly, and the acoustic pressure may be further reduced.

In some embodiments, the plurality of short blades 3 and the plurality of long blades 2 may be disposed alternately in a non-uniform manner. That is, along the circumferential direction of the shaft 1, the short blades 3 may be unevenly disposed, or the long blades 2 may be unevenly disposed, or both the short blades 3 and the long blades 2 are unevenly disposed.

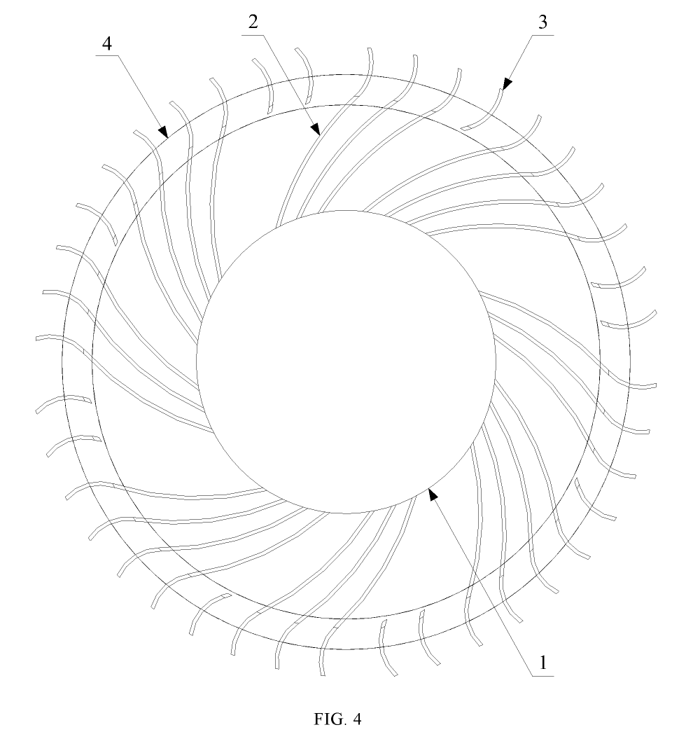

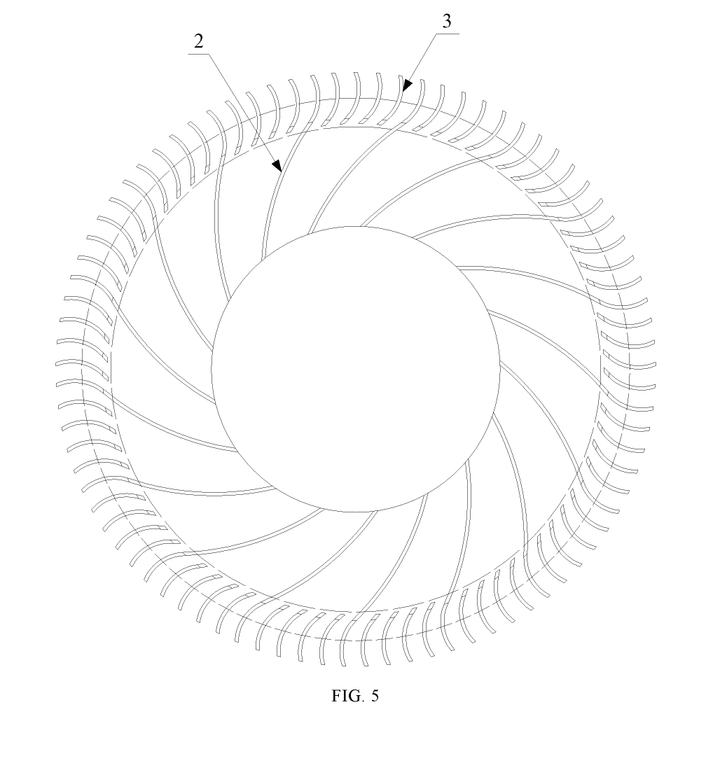

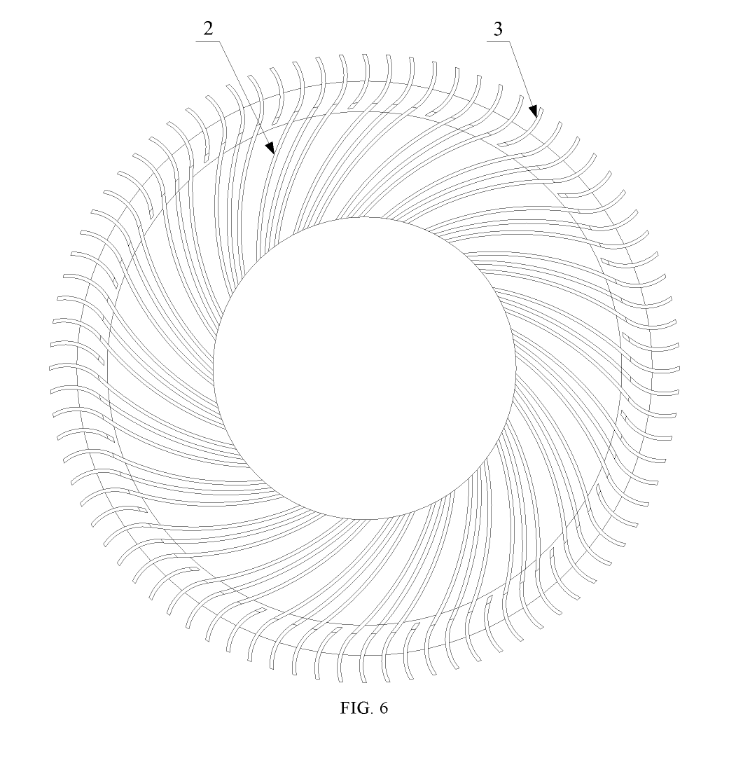

In some embodiments, different numbers of short blades 3 may be disposed between two adjacent groups of long blades 2, and the number of long blades 2 included in the two adjacent groups of long blades 2 may be the same or different. FIG. 4 illustrates a schematic view of an example showing both long blades and short blades arranged in a non-uniform manner.

As shown in FIG. 4, either one or two short blades 3 may be disposed between two adjacent long blades 2, and either three or four long blades 2 may be disposed between two adjacent short blades.

That is, the plurality of short blades 3 may include a plurality of first short-blade groups and a plurality of second short-blade groups arranged alternately, and the plurality of long blades 2 may include a plurality of first long-blade groups and a plurality of second long-blade groups arranged alternately. Further, the number of short blades in a first short-blade group may be different from the number of short blades in a second short-blade group, and the number of long blades in a first long-blade group may be different from the number of long blades in a second long-blade group. In the example shown in FIG. 4, the first short-blade group and the second short-blade group include one short blade and two short blades, respectively, and the first long-blade group and the second long-blade group include three long blades and four long blades, respectively. In some other examples, the first short-blade group and the second short-blade group may respectively include other numbers of short blades, and the first long-blade group and the second long-blade group may respectively include other number of long blades.

As a specific example, as shown in FIG. 4, along a circumferential direction of the shaft 1, three long blades 2 is first disposed, one short blade 3 is disposed adjacent to the three long blades 2 in a clockwise direction, four long blades 2 are disposed adjacent to the one short blade 3 in the clockwise direction, and two short blades 3 are disposed adjacent to the four long blades 2 in the clockwise direction, and so on.

The arrangement manners of the short blades 3 and the long blades 2 along the circumferential direction of the shaft 1 are not limited to those described above. For example, a plurality of short blades 3 may be disposed between any two neighboring long blades 2, or a plurality of long blades 2 may be disposed between any two neighboring short blades 3. FIG. 5 illustrates a schematic view of an example showing long blades and short blades arranged in another manner. As shown in FIG. 5, four short blades 3 are disposed between any two adjacent long blades 2. FIG. 6 illustrates a schematic view of an example showing long blades and short blades arranged in another manner. As shown in FIG. 6, three long blades 2 are disposed between any two adjacent short blades 3.

Further, referring again to FIG. 1 and FIG. 3, in some embodiments, a connection ring 4 is disposed connecting to the long blades 2, and the short blades 3 are disposed on the connection ring 4. The configuration manners of the short blades 3 can be various. For example, the connection ring 4 may be coaxial with the shaft 1, and the short blades 3 may be disposed at the connection ring 4. Thus, while the noise of the heat dissipation fan can be reduced, the impact of the connection ring 4 on the heat dissipation effect of the heat dissipation fan may be avoided. Further, the structure of the disclosed heat dissipation fan can be relatively simple, and the connection stability can be high. In some other embodiments, the short blades 3 may be coupled to the long blades 2 directly, or the connection ring 4 may be coupled to the shaft 1 through one or more connection rods.

To further improve the connection stability and working stability of the short blades 3, in some embodiments, the connection ring 4 may be coupled to all of the long blades 2, such that the short blades 3 may realize airstream dispersion in a more reliable and stable manner. Accordingly, the soundless performance of the disclosed heat dissipation fan may be further improved.

Based on the aforementioned description, the present disclosure further provides an electronic device. The electronic device includes a heat-generating component and a heat dissipation fan for cooling the heat-generating component. The heat dissipation fan may be a heat dissipation fan consistent with the disclosure, such as one of the example heat dissipation fans described above.

Further, the heat dissipation fan may be disposed in a mounting shell. The connection ring 4 may be disposed close to an inlet of the mounting shell, and an inner diameter of the connection ring 4 may be greater than a diameter of the inlet. By configuring the connection ring 4 to be near the inlet of the mounting shell and configuring the inner diameter of the connection ring 4 to be greater than the diameter of the inlet, the impact of the configuration of the connection ring 4 on the heat dissipation fan may be reduced. Accordingly, the overall performance of the heat dissipation fan is improved.

Because the electronic device includes the aforementioned heat dissipation fan, corresponding portions of foregoing descriptions may be referred to for the advantages of the electronic device that includes the heat dissipation fan. Related descriptions are not provided herein.

Various embodiments in the specification are described in a progressive manner, and each embodiment highlights their difference from other embodiments. The electronic device, and the whole or partial structures of the heat dissipation fan may be obtained by combining one or more aforementioned components.

The aforementioned illustrations of the disclosed embodiments teach those skilled in the relevant art to implement or employ the present disclosure. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A heat dissipation fan comprising:
a shaft; and
a plurality of blades configured along a circumferential direction of the shaft, wherein the plurality of blades includes:
one or more long blades, a head portion of each of the one or more long blades being coupled to the shaft, and
one or more short blades each disposed close to a tail portion of one of the one or more long blades, the one or more short blades being shorter than the one or more long blades.

2. The heat dissipation fan according to claim 1, wherein:
the one or more long blades include a plurality of long blades,
the one or more short blades include a plurality of short blades, and
the plurality of short blades and the plurality of long blades are disposed alternately.

3. The heat dissipation fan according to claim 1, wherein:
the one or more long blades includes a plurality of first long-blade groups and a plurality of second long-blade groups having different numbers of long blades,
the one or more short blades includes a plurality of first short-blade groups and a plurality of second short-blade groups having different numbers of short blades, and
the first long-blade groups, the first short-blade groups, the second long-blade groups, and the second short-blade groups are arranged alternatively.

4. The heat dissipation fan according to claim 1, wherein:
along the circumferential direction of the shaft, a plurality of short blades are disposed between any two adjacent long blades.

5. The heat dissipation fan according to claim 1, wherein:
along the circumferential direction of the shaft, a plurality of long blades are disposed between any two adjacent short blades.

6. The heat dissipation fan according to claim 1, further comprising:
a connection ring coupled to at least one of the one or more long blades,
wherein the one or more short blades are coupled to the connection ring.

7. The heat dissipation fan according to claim 6, wherein:
the connection ring is coupled to all of the one or more long blades.

8. An electronic device comprising:
a heat-generating component; and
a heat dissipation fan, wherein the heat dissipation fan includes:
a shaft, and
a plurality of blades configured along a circumferential direction of the shaft and including:
one or more long blades, a head portion of each of the one or more long blades being coupled to the shaft, and
one or more short blades each disposed close to a tail portion of one of the one or more long blades, the one or more short blades being shorter than the one or more long blades.

9. The display electronic device according to claim 8, wherein:
the heat dissipation fan further includes a connection ring coupled to all of the one or more long blades, and
the one or more short blades are coupled to the connection ring.

10. The electronic device according to claim 9, further comprising:
a mounting shell enclosing the heat dissipation fan,
wherein:
the connection ring is disposed close to an inlet of the mounting shell, and
an inner diameter of the connection ring is greater than a diameter of the inlet of the connection ring.

11. The electronic device according to claim 8, wherein:
the one or more long blades include a plurality of long blades,
the one or more short blades include a plurality of short blades, and
the plurality of short blades and the plurality of long blades are disposed alternately.

12. The electronic device according to claim 8, wherein:
the one or more long blades includes a plurality of first long-blade groups and a plurality of second long-blade groups having different numbers of long blades,
the one or more short blades includes a plurality of first short-blade groups and a plurality of second short-blade groups having different numbers of short blades, and
the first long-blade groups, the first short-blade groups, the second long-blade groups, and the second short-blade groups are arranged alternatively.

13. The electronic device according to claim 8, wherein:
along the circumferential direction of the shaft, a plurality of short blades are disposed between any two adjacent long blades.

14. The electronic device according to claim 8, wherein:
along the circumferential direction of the shaft, a plurality of long blades are disposed between any two adjacent short blades.
